(19) United States
(12) Patent Application Publication
(10) Pub. No.: US 2008/0223746 A1
(43) Pub. Date: Sep. 18, 2008

(54) Display Device Arrangement and Container

(75) Inventors: Bas Jan Emile Van Rens, Heemstede (NL); Gerwin Hermanus Gelinck, Valkenswaard (NL); Hjalmar Edzer Ayco Huitema, Veldhoven (NL); Dagobert Michel De Leeuw, Eersel (NL); Aloysius Jozef Nijman, Riethoven (NL)

Correspondence Address: LEYDIG VOIT & MAYER, LTD, TWO PRUDENTIAL PLAZA, SUITE 4900, 180 NORTH STETSON AVENUE, CHICAGO, IL, 60601-6731, US

(73) Assignee: KONINKLIJKE PHILIPS ELECTRONICS N.V., Eindhoven (NL)

(21) Appl. No.: 10/572,927

(22) PCT Filed: Sep. 24, 2004
(86) PCT No.: PCT/IB2004/051846

§ 371 Date: May 22, 2008

(30) Foreign Application Priority Data
Sep. 27, 2003 (GB) 0322686.7

(51) Int. Cl. B65D 81/24; B65D 81/20; H01L 51/00

(52) U.S. Cl. 206/454; 206/701; 206/213.1; 257/40

(57) ABSTRACT

A display device arrangement (1) comprises a display device (10). The display device (10) comprises a component being degradable upon exposure to an environmental factor such as light or moisture. Such a component may for instance be an organic semiconductor or an organic electro-optical material. The display device arrangement (1) further comprises a container (100) for storing the display device (10). The container (100) comprises protective means (120) that are detached from the flexible display device (10) for reducing the exposure of the degradable component to the environmental factor. Consequently, the lifetime of the display device (10) is increased without having to attach protective barriers to the display device (10) itself.

The present invention relates to a display device comprising a component being degradable upon exposure to an environmental factor.

The present invention further relates to a container for storing such a display device.

Nowadays, new types of display devices based on new materials are attracting a considerable amount of attention. Such new materials include organic semiconductor materials such as organic light emitting diodes (OLEDs) and organic transistors, organic polymer based flexible substrates, new electro-optical materials such as organic electrophoretic materials and so on. The attractive properties of such materials include their low weight, low cost and their ability to enable potential new application domains for display devices, e.g., flexible display devices, especially if the flexibility of the display device is high enough to allow the display device to be rolled-up without damaging it.

However, a fundamental complication of developing such devices is the sensitivity of the new materials to environmental factors such as light and oxygen and/or moisture in the air, which degrade those materials over time, causing a loss in performance of the display device.

In U.S. Pat. No. 6,592,969, this problem is tackled by attaching a protective element including a thin layer of glass to the display area of a display device having a flexible substrate to protect an electrically active organic layer from exposure to such environmental factors and increase the lifetime of the display device.

However, the addition of such a protective element some unwanted consequences. For instance, the protective element has a restrictive influence on the flexibility of the display device, which is unwanted when trying to achieve a rollable display device. Furthermore, the addition of the protective element increases the complexity and the weight of the display device, which may also be unwanted.

The present invention seeks to extend the lifetime of a display device according to the opening paragraph without increasing the complexity of such a display device.

According to an aspect of the present invention, there is provided a display device arrangement comprising a display device comprising a component being degradable upon exposure to an environmental factor, and a container for storing the display device, the container comprising protective means for reducing the exposure of the component to the environmental factor.

The present invention is based on the recognition that display devices including degradable components, e.g., organic materials, can be used as disposables because of their low manufacturing cost. It is foreseen that customer satisfaction is primarily influenced by the handling characteristics of the display device such as its weight and its flexibility in case of flexible display devices rather than its lifetime, as long as the lifetime can be prolonged to a certain extent. Since it is anticipated that such display devices will be in idle state for the majority of their lifespan, either during their shelf life or during the period of active use, the present invention protects such a display device from exposure to harmful environmental factors such as the exposure to air or light during those inactive periods. This has the advantage that a display device including degradable components is obtained with a substantially increased lifetime compared to unprotected display devices having such components, without for instance compromising the flexibility of a flexible display device, because the protective means are detached from the display device itself.

The protective means may comprise a light shielding material, the light shielding material covering at least a substantial part of the container, an inert gas, a getter material or combinations of these embodiments to protect the flexible display device from exposure to light, oxygen, moisture or combinations thereof. This is particularly advantageous to extend the shelf life of the display device having degradable components. This is an important advantage, because it is likely that such a display device will spend most of its life on the shelf.

Although containers having protective means to protect items during their shelf life are known per se, e.g., a canister containing air-sensitive chemicals under a nitrogen atmosphere, it is pointed out that it is not obvious to remove the protective barrier from a display device having degradable components and replace it with protective means in the packaging of such a display device, thus rendering the display device arrangement of the present invention both novel and inventive over the prior art.

In an alternative embodiment, the container is arranged to store the display device during an inactive period of the display device; and the container comprises an opening for at least partially exposing the display device during an active period of the display device. The display arrangement of the present invention can also be used to protect a display device having degradable components during the inactive periods of its active life. Such a display device arrangement may be a part of an electronic device such as a mobile phone. Also, the display device may be flexible, in which case the container is arranged to store the display device in a flexed state such as a rolled-up state.

Advantageously, the display device arrangement comprises a lid for closing the opening of the container; the container comprising a chamber comprising the getter material, the chamber comprising a further lid; and means for closing the further lid responsive to removing the lid from the opening. Such an arrangement increases the lifetime of the getter material, because it is not exposed to the air when the container is opened.

Alternatively, the opening comprises an airtight seal to reduce the exposure of the getter material to the air.

It is a further advantage if the getter material is integrated on a flexible layer, the flexible layer being arranged to cover a flexed part of a flexible display device. Such a flexible layer, which may comprise polydimethylsiloxane (PDMS), can be rolled tightly against the flexed part of the display device to reduce the exposure of the flexed part of the display device to moisture.

It is another advantage if the inside of the container has an internal pressure; and the container further comprises a valve for maintaining the internal pressure, the valve comprising the getter material. Upon a drop in pressure caused by the unrolling of the display device, the outside air that enters the container through the valve will have the pass the getter material. Consequently, a substantially moisture-free atmosphere will be maintained inside the container, which prolongs the lifetime of the part of the flexible display device residing inside the container.

According to a further aspect of the invention, there is provided a container for storing a display device comprising a component being degradable upon exposure to an environmental factor; the container comprising protective means for reducing the exposure of the component to the environmental factor. Such containers enable the production of degradable display devices without protective barriers, which, for instance, can have improved flexibility characteristics compared to prior art display devices having such protective barriers.

In an embodiment, the container is arranged to store the display device during an inactive period of the display device; the container comprises an opening for at least partially exposing the display device during an active period of the display device; and the protective means comprise a getter material.

The invention is described in more detail and by way of non-limiting examples with reference to the accompanying drawings, wherein:

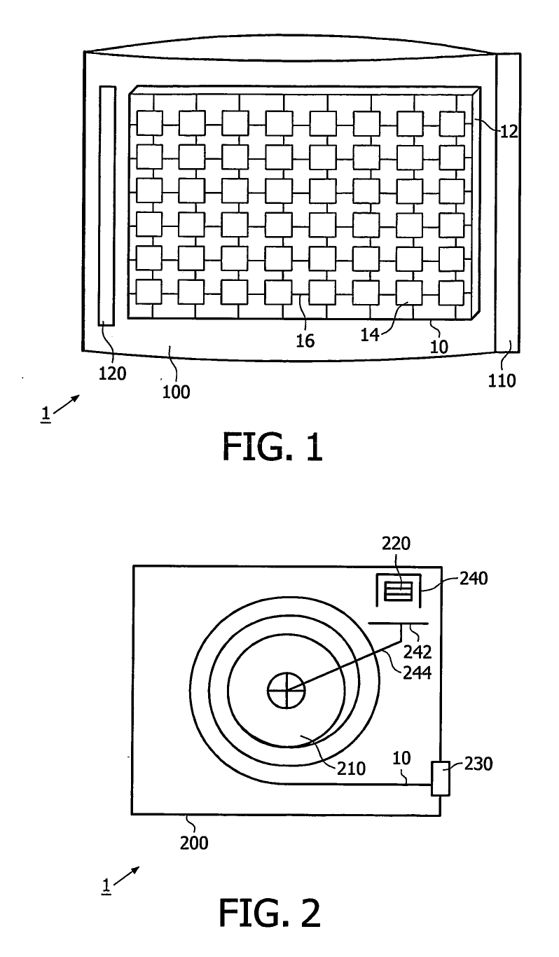

FIGS. 1-4 show various embodiments of the display device arrangement of the present invention.

It should be understood that the Figures are merely schematic and are not drawn to scale. It should also be understood that the same reference numerals are used throughout the Figures to indicate the same or similar parts.

FIG. 1 shows a display device arrangement 1 including a display device 10 stored in a container 100. The display device 10 typically includes a substrate 12, a plurality of pixels 14 and a plurality of electrodes 16 for connecting the pixels 14 to the appropriate driver circuitry. The substrate 12 may be a flexible substrate formed from an organic polymer or another suitable flexible material. In the case of an active matrix array display device, the pixels 14 may include a thin film transistor, which may include an organic semiconductor material. Again, this may be any known suitable organic semiconductor material, such as a polythiophene derivative or a polyphenylvinylene derivative. Typically, the pixels 14 include an electro-optical display element including an organic liquid crystal material, an organic semiconductor material like a light emitting organic polymer or an electrophoretic material, for example. The aforementioned organic materials are typical examples of components that are degradable upon exposure to an environmental factor such as light, air and moisture, i.e., components that undergo unwanted chemical reactions as a result of their exposure to such factors.

The container 100 protects the various degradable components of the display device 10 from exposure to environmental factors during the shelf life of the display device 10. In the embodiment shown in FIG. 1, the container 100 is a plastic bag having a seal 110. The plastic bag may be lined with a black out lining such as an aluminium foil to prevent exposure of the display device 10 to incident light. The container 100 may contain a getter material 120 to remove moisture from the atmosphere inside the container 100, e.g., the plastic bag, thus reducing the exposure of the flexible display device 10 to said moisture. The getter material 120 may comprise a silica gel or a hygroscopic salt such as sodium chloride. Such salts have been demonstrated to lower the relative humidity of the air inside the container 100 to around 10%. If even lower moisture levels are required, stronger hygroscopic materials such as sulphuric acid in an appropriate protective container may be used. The container 100 may also include an inert atmosphere such as nitrogen to protect the display device 10 from exposure to oxygen.

It will be obvious to those skilled in the art that the container 100 can come in many other forms. For instance, the container 100 may be a metal canister, a box with an airtight lid or any other suitable packaging without departing from the scope of the present invention.

At this stage, it is pointed that that in the claims, the protective means for reducing the exposure of the component to the environmental factor are to include protective means that exclude the exposure of the organic material to the environmental factor.

FIGS. 2-4 show various embodiments of display device arrangements 1 that are intended to extend the active lifetime of the display device 10. In the FIGS. 2-4, the display device 10 is depicted as a flexible display device. It is, however, emphasized that this is by way of non-limiting example only; non-flexible display devices having degradable components can also benefit from the protective measures depicted in those Figs and their accompanying detailed description.

In FIG. 2, the display device arrangement 1 includes a container 200, which has a spool 210 for storing the flexible display device 10 in a flexed state, e.g., a rolled-up state. The diameter of the spool 210 may be chosen in accordance with the flexibility of the flexible display device 10. The container 200, which may be formed from a light-shielding material, e.g., a suitable metal or plastic, is shown to have a rectangular shape, but it will be understood that other shapes such as a cylindrical shape, for instance, are equally feasible. The spool 210 typically is connected to a handle not shown outside the container 200 for to facilitate a user to store the display device 10. The container 200 has an opening with a fitting lid 230 through which the flexible display device 10 can be unrolled. The lid 230 is attached to an end of the flexible display device 10 to serve as a grip for facilitating the unrolling of the flexible display device 10.

The container 200 further includes a chamber 240 in which a getter material 220 is placed. The getter material 220 may be the same as the getter material 120. The chamber 240 has a further lid 242 attached to a lever 244, the lever 244 being attached to the spool 210. In the initial position of the spool 210, i.e., when the lid 230 is in place and the flexible display device 10 is stored, the further lid 242 is forced away from the chamber 240 by the lever 244, thus allowing contact between the getter material 220 and the internal atmosphere of the container 200. This reduces the exposure of the flexed display device 10 to moisture, which slows down the degradation of the degradable components of the flexible display device 10, thus prolonging its lifetime.

As soon as the spool 210 is forced from its initial position, i.e., as soon as the lid 230 is removed from the container 200 and the display device 10 is unrolled, the lever 244 will press the further lid 242 against the opening of the chamber 240, and the getter material 220 will be protected from the incoming air through the opening of the container 200. This extends the lifetime of the getter material 220.

It will be obvious that many alternatives of the embodiment shown in FIG. 2 can be thought of. For instance, the inside of the container may be fitted with a light sensor coupled to small electromotor, which is attached to the further lid 242 and closes the further lid 242 as soon as incident light through the opening of the container 200 is detected. Alternatively, the lid 230 may be fitted with a protruding feature that pushes the further lid 242 away from the chamber 240 upon inserting the lid 230 in the opening of the container 200. The lid 242 may also be omitted if the opening of the container 200 only allows small amounts of air to penetrate the container 200. This can for instance be realized by fitting an airtight seal such as a D-ring around the edges of the opening of the container 200. Also, in case of a non-flexible display device, it will be obvious that the spool 210 can be omitted.

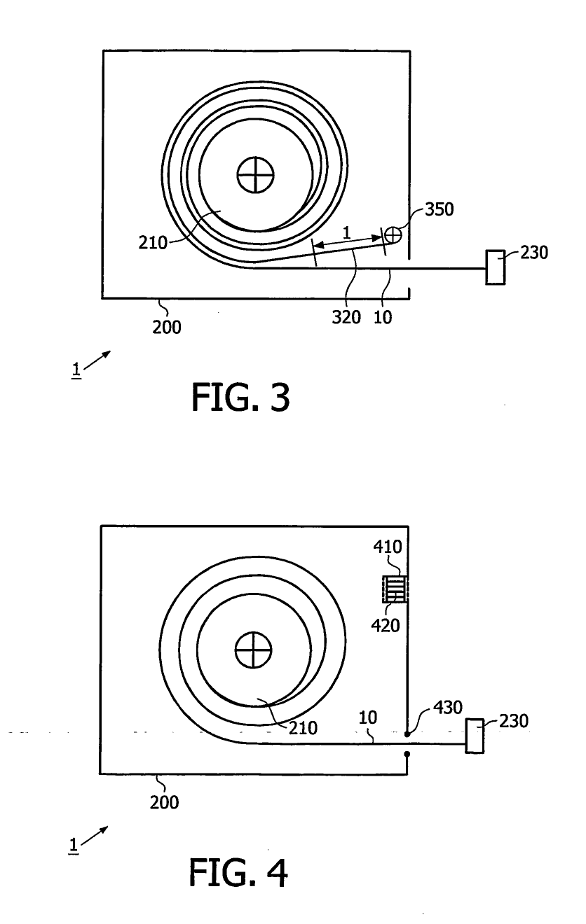

FIG. 3 shows an alternative embodiment of the display device arrangement 1 for extending the active lifetime of the flexible display device 10. In this embodiment, the getter material is integrated on a flexible foil 320. One end of the flexible foil 320 is attached to the spool 210, whereas the other end of the flexible foil 320 is attached to a further spool 350, which is coupled to the winding mechanism of the spool 210 to ensure synchronous rotation of both spools 210 and 350. In a totally unrolled state of the flexible display device 10, the flexible foil 320 will mainly reside on the further spool 350 in a rolled-up state. Upon rolling up the flexible display device 10, the flexible foil 320 will be unrolled from the further spool 350, and will be rolled-up onto the spool 210 together with the flexible display device 10 in such a way that a side of the flexible foil 320 carrying the getter material will be in close contact with the surface of the flexible display device 10 that is most degradable upon exposure to moisture, thus reducing the exposure of the flexible display device 10 to moisture in its flexed state. Typically, this surface is the surface of the flexible display device 10 carrying the pixels 14.

Because the flexible foil 320 is rolled-up onto the further spool 350 upon unrolling the flexible display device 10, the exposure of the getter material on the flexible foil 320 to the moisture is mainly limited to the length l shown in FIG. 3, thus protecting the bulk of the getter material from rapid saturation with moisture.

An embodiment of the flexible foil 320 may be produced in the following manner. As a material for the flexible foil, polydimethylsiloxane (PDMS) may be chosen, e.g., Sylgard 184 from the Du Pont chemical company. One equivalent of Sylgard cure is mixed with 10 equivalents of Sylgard base. Subsequently, crystals of a hygroscopic salt, e.g., sodium chloride crystals, are dispersed over a large area, e.g., the bottom of a large container. The Sylgard mixture is poured over and mixed with the salt crystals, thus dispersing the salt crystals through the Sylgard mixture. The mixture is heated at 65° C. overnight to polymerize the mixture and form a PDMS foil with integrated getter material. Optionally, prior to the polymerization step, the mixture may be degassed in an evacuated desiccator to reduce the amount of air bubbles in the mixture.

The type of salt determines the relative humidity that will be established in an enclosed environment. A non-exhaustive list of salts and their equilibrium relative humidities can for instance be found in the handbook of chemistry and physics, 64th edition, CRC press, Boca Raton.

Another embodiment of a display device arrangement 1 for extending the active lifetime of the flexible display device 10 is shown in FIG. 4.

The opening of the container 200 is fitted with an air-tight seal 430, e.g., a d-ring, to maintain an internal pressure in the container 400 by preventing the influx of air into the container 200 through its opening. In addition, the container 200 has a valve 410 containing a getter material 420, the valve 410 connecting the inside of the container 200 with the outside world. The getter materials 420 may be any suitable getter material including the materials mentioned as embodiments for the getter material 120. The container 200 may be initially filled with an inert gas like nitrogen to protect the organic semiconductor materials on the flexible display device 10.

Upon unrolling of the flexible display device 10 through the opening of the container 200, the internal pressure of the container will drop due to reduction of the volume of the flexible display device 10 that resides inside the container 200. Consequently, air will start flowing into the container 200 through the valve 410 to compensate for the drop in internal pressure. The incoming air has to pass through the getter material 420, thus reducing the amount of moisture in the incoming air. As a result, the flexible display device 10 will benefit from a reduced exposure to moisture in its rolled-up state, thus increasing its lifetime.

It is emphasized that the containers 100 and 200 shown in FIG. 1-4 for storing a display device 10 can be produced and sold separately with the various embodiments of the protective means integrated in the containers to facilitate the intended protection of a display device 10 having components that are degradable upon exposure to an environmental factor.

It should be noted that the above-mentioned embodiments illustrate rather than limit the invention, and that those skilled in the art will be able to design many alternative embodiments without departing from the scope of the appended claims. In the claims, any reference signs placed between parentheses shall not be construed as limiting the claim. The word “comprising” does not exclude the presence of elements or steps other than those listed in a claim. The word “a” or “an” preceding an element does not exclude the presence of a plurality of such elements. The invention can be implemented by means of hardware comprising several distinct elements. In the device claim enumerating several means, several of these means can be embodied by one and the same item of hardware. The mere fact that certain measures are recited in mutually different dependent claims does not indicate that a combination of these measures cannot be used to advantage.

1. A display device arrangement (1) comprising:
a display device (10) comprising a component being degradable upon exposure to an environmental factor; and
a container (100, 200) for storing the display device (10), the container (100, 200) comprising protective means (120, 220, 320, 420) for reducing the exposure of the component to the environmental factor.

2. A display device arrangement (1) as claimed in claim 1, wherein the protective means comprise a light shielding material, the light shielding material covering at least a substantial part of the container (100).

3. A display device arrangement (1) as claimed in claim 1, wherein the protective means further comprise an inert gas.

4. A display device arrangement (1) as claimed in claim 1, wherein the protective means further comprise a getter material (120, 220, 320, 420).

5. A display device arrangement (1) as claimed in claim 4, wherein:
the container (200) is arranged to store the display device (10) during an inactive period of the display device (10); and
the container (200) comprises an opening for at least partially exposing the display device (10) during an active period of the display device (10).

6. A display device arrangement (1) as claimed in claim 5, wherein the display device (10) is flexible, and the container (200) is arranged to store the display device (10) in a flexed state.

7. A display device arrangement (1) as claimed in claim 5, wherein:
the display device arrangement (1) comprises a lid (230) for closing the opening of the container (200);
the container comprising a chamber (240) comprising the getter material (220), the chamber (240) comprising a further lid (242); and
means (244) for closing the further lid (242) responsive to removing the lid (230) from the opening.

8. A display device arrangement (1) as claimed in claim 6, wherein the getter material is integrated on a flexible foil (320), the flexible foil (320) being arranged to cover a flexed part of the flexible display device (10).

9. A display device arrangement (1) as claimed in claim 9, wherein the flexible foil (320) comprises polydimethylsiloxane.

10. A display device arrangement (1) as claimed in claim 5, wherein the opening comprises an airtight seal (430).

11. A display device arrangement (1) as claimed in claim 10, wherein the inside of the container (200) has an internal pressure; and
the container further comprises a valve (410) for maintaining the internal pressure, the valve comprising the getter material (420).

12. A display device arrangement (1) as claimed in claim 5, wherein the display device arrangement (1) is a part of an electronic device.

13. A container (100, 200) for storing a display device (10) comprising a component being degradable upon exposure to an environmental factor; the container (100) comprising protective means (120, 220, 320, 420) for reducing the exposure of the component to the environmental factor.

14. A container (200) as claimed in claim 13, wherein:
the container (200) is arranged to store the display device (10) during an inactive period of the display device (10);
the container (200) comprises an opening for at least partially exposing the display device (10) during an active period of the display device (10); and
the protective means comprise a getter material (220, 320, 420).
